(19) United States
(12) Patent Application Publication
(10) Pub. No.: US 2024/0349441 A1
(43) Pub. Date: Oct. 17, 2024

(54) Cable parking system for a network element and method thereof

(71) Applicant: Ciena Corporation, Hanover, MD (US)

(72) Inventors: Fabien Colton, Kars (CA); Simon J. E. Shearman, Carleton Place (CA); Daniel Rivaud, Ottawa (CA)

(21) Appl. No.: 18/301,753

(22) Filed: Apr. 17, 2023

(51) Int. Cl. H05K 7/14; H05K 5/02

(52) U.S. Cl. CPC H05K 7/1491; H05K 5/0247; H05K 5/0286

(57) ABSTRACT

Systems and methods for a cable parking system for a network element and a method thereof comprising a filler card configured to be inserted in a slot of a plurality of slots, wherein the network element includes a shelf containing the plurality of slots. The network element including a park module configured to attach to a faceplate of the filler card and configured to receive and hold a plurality of cables for connectivity between the plurality of slots. The cable parking system where the filler card is inserted in lieu of a working card that includes one or more of a client card, a line card, a fabric card, and a combination thereof, and wherein the park module supports the plurality of cables for a future working card. The cable parking system further comprising one or more pluggable module holders each configured to insert in the park module and each configured to hold one or more pluggable modules with a cable connected thereof.

### FIELD OF THE DISCLOSURE

The present disclosure relates generally to networking and computing. More particularly, the present disclosure relates to systems and methods for a cable parking system for a network element and a method thereof.

### BACKGROUND OF THE DISCLOSURE

Networking, as well as computing, storage, and other types of data processing devices, are realized by physical entities, referred to as a network element. The physical entities are hardware with implementations in a chassis, shelf, rack-mounted units, etc. that can be mounted in frames, racks, cabinets, etc. A chassis or shelf is a physical housing that is meant to receive modules (also referred to as cards, line cards, circuit packs, blades, etc.). A rack-mounted unit (also referred to as a “pizza box”) is an integrated unit that is configured to mount in the rack or frame and connect to other units or modules in the rack or frame. Traditionally, in chassis or shelf implementations, there is a backplane where all the modules are connected to. Of course, there can also be a backplane in a rack-mounted unite. Disadvantageously, a backplane is purely electrical and there are benefits to replace the backplane with cabled interconnect between modules. There exists a need from customers to expand rack-mounted network modules in the future with different types of working cards that includes one or more of a client card, a line card, a fabric card, and a combination thereof while also maintain airflow balancing in addition to providing EMI integrity inside networking rack, chassis, shelf, etc.

### BRIEF SUMMARY OF THE DISCLOSURE

According to one implementation of the present disclosure, a cable parking system for a network element, including a filler card configured to be inserted in a slot of a plurality of slots, wherein the network element includes a shelf containing the plurality of slots. The network element including a park module configured to attached to a faceplate of the filler card and configured to receive and hold a plurality of cables for connectivity between the plurality of slots. The cable parking system where the filler card is inserted in lieu of a working card. A working card is a term to include a client card, a line card, a fabric card, and a combination thereof, and wherein the park module supports the plurality of cables for a future working card.

According to another implementation, the cable parking system including one or more pluggable module holders, each configured to insert in the park module and each configured to hold one or more pluggable modules with a cable connected thereto where a pluggable module of the one or more pluggable modules is a Quad Small Form Factor Pluggable (QSFP) or a variant thereof. The one or more pluggable module holders are removable from the park module with the plurality of cables attached thereto, for replacing the filler card with a working card that includes one or more of a client card, a line card, a fabric card, and a combination thereof. The plurality of cables can include any of an Active Electrical Cable (AEC), Active Optical Cable (AOC), and Direct Attach Cable (DAC) and the one or more pluggable module holders protectively support an end of each of the plurality of cables.

According to yet another implementation the cable parking system including a filler card and a park module, such that the filler card and the park module support airflow and Electromagnetic Interference (EMI) protection for the shelf. The cable parking system wherein the network element is pre-cabled prior to shipment utilizing the cable parking system.

### BRIEF DESCRIPTION OF THE DRAWINGS

The present disclosure is illustrated and described herein with reference to the various drawings, in which like reference numbers are used to denote like system components/method steps, as appropriate, and in which:

FIGS. 1A-1C illustrate cross sectional views for an extrusion profile of a faceplate for a circuit pack filler, according to various embodiments.

FIGS. 2A-2B are illustrations of the extrusion profile used as a faceplate for the baseplate of the circuit pack filler, according to various embodiments.

FIGS. 3A-3B illustrate how the machined extrusion faceplate is placed against the baseplate.

FIG. 4 illustrates a complete fully wrapped EMI shielded circuit pack filler which can be installed into a networking rack.

FIGS. 5A-5B are isometric diagrams for the assembled circuit pack filler including novel presence detection, according to various embodiments.

FIGS. 6A-6B illustrate the circuit filler pack interface with the backplane, according to various embodiments.

FIG. 7 is a detailed view of one side of the filler pack inserted into the backplane with presence detection interfaces.

FIG. 8 is an overhead view illustrating the top of the filler card with parking slots for fabric cables.

FIG. 9A-9B are perspective views of the filler card with parking slots and fabric cables installed.

FIG. 10 illustrates an isometric view of a fully expandable filler card for pre-cabling data links, according to various embodiments.

FIG. 11 illustrates an isometric view of a fully expandable filler card for pre-cabling data links including a QSFP-DD holder, according to various embodiments.

FIG. 12 illustrates an isometric view of the parking module for a filler card, according to various embodiments.

FIGS. 13A-13B illustrate detailed views of the pluggable module holders.

FIGS. 14A-14C are detailed illustrations for various park and filler card modules, according to various embodiments.

FIGS. 15A-15B are front views of a networking rack including filler cards and park modules with pre-assembled cabling.

FIG. 16 is a flowchart illustrating an embodiment for a method of packaging and shipping a network element with a cable parking system.

### DETAILED DESCRIPTION OF THE DISCLOSURE

Again, the present disclosure is directed to systems and methods for a cable parking system for a network element and a method thereof including a filler card configured to be inserted in a slot of a plurality of slots, wherein the network element includes a shelf containing the plurality of slots and a park module attached to a faceplate of the filler card configured to receive and hold cables for connectivity between the plurality of slots.

### Backplane

A backplane has traditionally provided various functions. It can carry power to modules, control signals to modules from control cards, and provide fabric switching paths between working modules (fabric modules to client modules). In some of the embodiments described herein, we have removed power carrying from the backplane and we have removed fabric switching from the backplane, but we can use a backplane to carry control signals from control cards to each module. The power distribution can be replaced with power distribution busbars, and the fabric signal switching can be replaced with cable connections on faceplates from card to card. The cable connections are configurable between modules in a shelf or between modules in different shelves. It is advantageous to pre-cable a specific known configuration and have the cable ends parked in a park module for future connect. This prevents the operator from having to purchase all the modules needed for this specific but planned configuration from the start. With the present disclosure, the operator can gradually remove a park filler module which has pre-cabled/configured fabric connections, and replace them with working modules as required. And it therefore allows all fabric connections to be in place from day one, with no need to add fabric cables to the system as cards added to the system one at a time.

### EMI Shielded Circuit Pack Filler

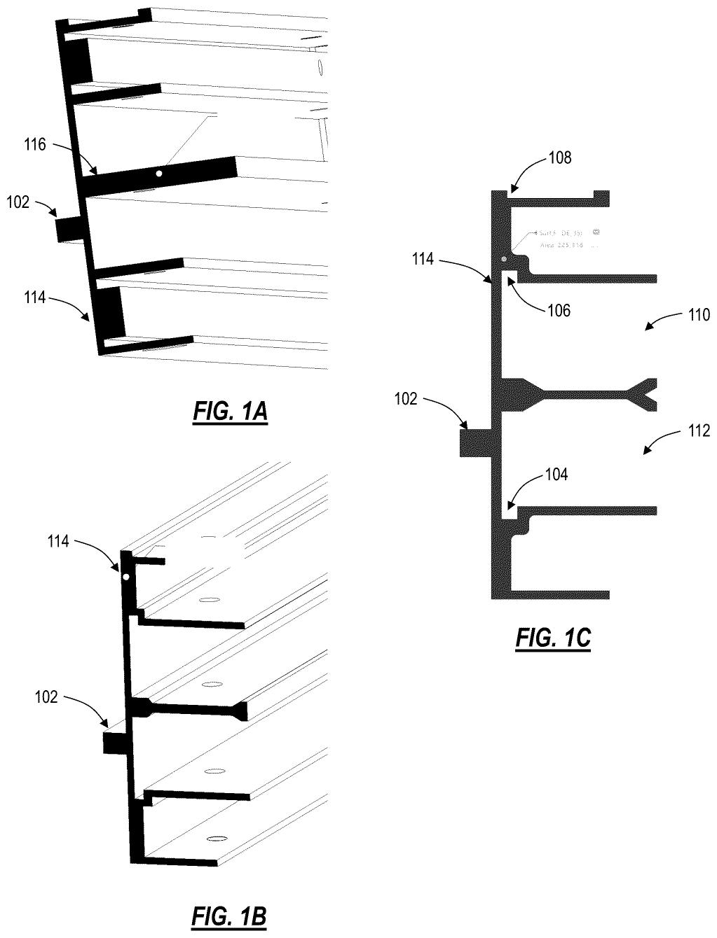

FIG. 1A-1C illustrate cross sectional views for an extrusion profile of a faceplate for a circuit pack filler. The faceplate 114 is shown wherein the extrusion profile includes features to mock a printed circuit board (PCB) edge 102. Also included in the profile are sheet metal slots or pockets to create a faraday cage which can be filled with Electromagnetic Interference (EMI) gaskets (104, 106, 108). The EMI gaskets (104, 106, 108) assist in maintaining the position of the card in the circuit pack filler and preventing gasket creep thereby maintaining the faraday cage. The extrusion profile includes features to allow a pocket intended to support a plurality of temporary optical module holders (110, 112). The row divider (116) exists to separate the optical modules. Pluggable optical modules may be inserted into the module holders (110, 112) of the circuit pack filler in a way where the pluggable optical modules slide into place and the faceplate 114 provides EMI protection between the pluggable optical modules as well as between the pluggable optical modules and the other components that are installed on the shelf. This faceplate profile can reduce costs by creating a circuit pack filler without the use of expensive printed circuit boards (PCBs) and also reduces the number of EMI gaskets needed.

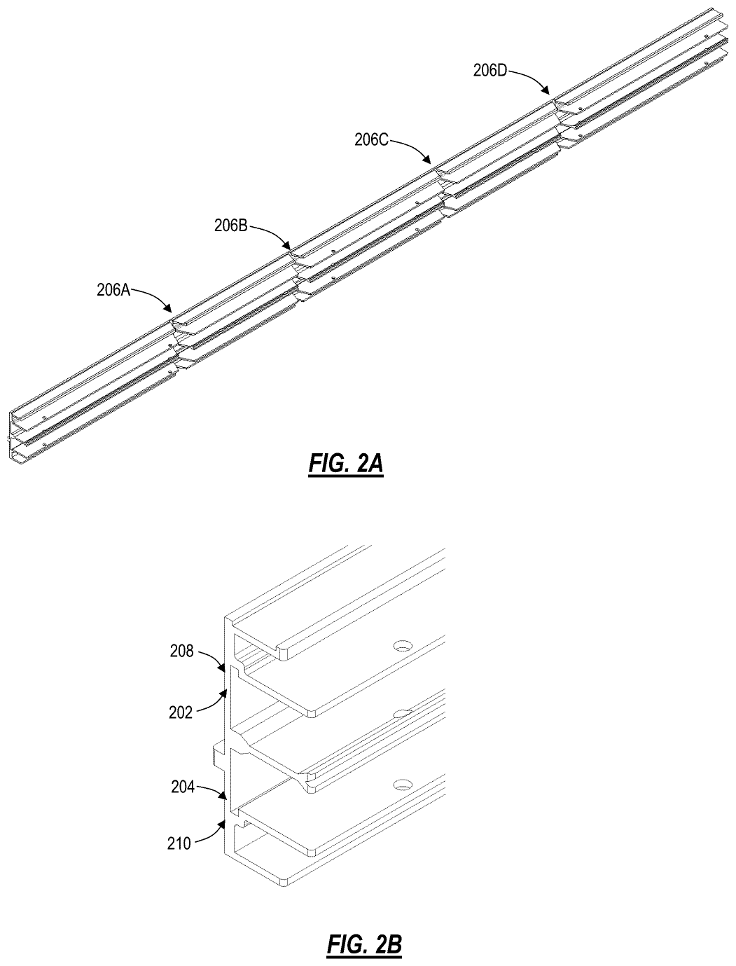

FIGS. 2A-2B are illustrations of the extrusion profile used as a faceplate for the baseplate of the circuit pack filler, according to various embodiments. As shown in FIG. 2A the length of the extrusion is machined in a way to allow bend reliefs (206A-206D) that will form the corners of the baseplate which will allow the extrusion to be manually bent around the baseplate 304. The EMI gasket pockets (208, 210) that are formed from the machined extrusion allow the small EMI gaskets (202, 204) to be fitted into those pockets prior to bending the faceplate extrusion over the baseplate. The extrusion is manufactured with a length, width, and bend relief features in order to wrap the front shape of the baseplate 304. The extrusions that exist on the faceplate 302 replace the need for an expensive printed circuit board (PCB) as the guide for sliding into the circuit pack filler. The extrusion profile manufactured as part of the faceplate design are low in cost and small in cross sectional area when compared to a PCB.

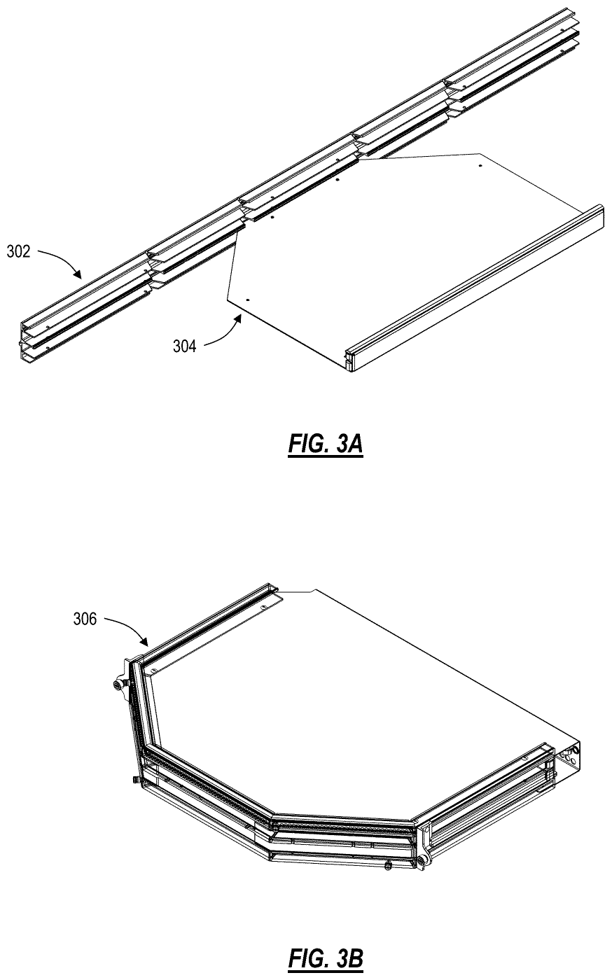

FIGS. 3A-3B illustrate how the machined extrusion faceplate is placed against the baseplate. The straight extrusion with machined notches can be placed against the baseplate 304 which acts as the base of the faraday cage. The assembling technician can bend the faceplate 302 around the baseplate 304 to create a precisely controlled shape 306. The notches that exist in the extrusion (206A-206D) are precisely machined to create bend locations and are deep enough to prevent the need for a bending machine. The faceplate 302 wraps the three sides of the baseplate 304 and the extrusion profile is such that the assembled apparatus provides EMI shielding as well as support for the circuit pack filler. A circuit pack filler can be installed in a networking rack where the shelf created by the circuit pack filler can provide physical support as well as EMI protection for the working cards that may be inserted. Working cards include line cards, client cards, and fabric cards, where each card can provide multiple functions.

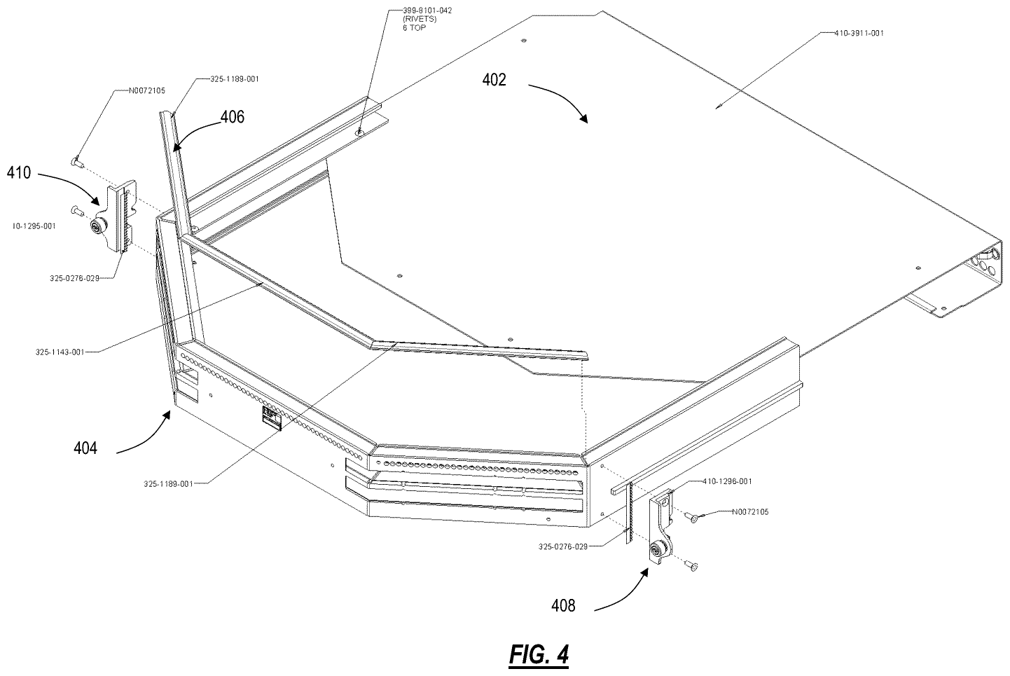

FIG. 4 illustrates a complete fully wrapped EMI shielded circuit pack filler which can be installed into a networking rack. A top plate 402 is inserted into the extrusion channel 404, where the extrusion channel 404 can include latches or mounting features (408, 410) to the front corners of the circuit pack without the faraday cage. These mounting features are used to mount this circuit pack filler to the shelf and to protect against seismic and office vibrations. The circuit pack is shaped to allow air to flow over the top and bottom in controlled amounts, holes are machined in the faceplate to control the amount of area the air has to enter the card slot. The circuit pack prevents larger amounts of air flowing into the middle of a slot. It is best to direct air to the top and bottom of the slot toward adjacent cards that may need the air flow for cooling. In another embodiment of the invention the top and bottom plates can be combined into a single part, however the single part requires enough volume to pay for the deep channel bending tool. The EMI pockets can be machined in the front of the faraday cage faceplate with a shape such that the optical modules can be held in place for storage. Top front gaskets 406 are included and installed on the inside of the faceplate and seal the top plate 402 to the faceplate. Features in the extrusion exists to provide support between the rows of optical modules. The row divider (116) exists to separate the optical modules. Pluggable optical modules may be inserted into the module holders 904,1102) of the circuit pack filler in a way where the pluggable optical modules slide into place and the faceplate 114 provides EMI protection between the pluggable optical modules as well as between the pluggable optical modules and the other components that are installed on the shelf.

Most typical industry empty modules, also referred to as filler card modules use a PCB mounted to a faceplate. The faceplate provides the EMI seal to the shelf and to the adjacent circuit pack. Once the slot becomes large, the PCB becomes very large and expensive. An empty PCB whose function is solely to guide the module into the slot becomes a cost inhibitor for large filler cards. Smaller slot filler cards can be precision injection molded to reduce cost however the cost of a precision injection mold increases exponentially with the size of a PCB such that the mold price is too expensive to consider for filler card modules. Using only a faceplate to seal a slot does not give the option of detecting the presence of a slot filler and does not allow the customer to have available alarms to notify if air flow is being restricted. In this embodiment a filler card detection mechanism can be deployed for card presence detection. Card presence detection can include connectors mounted to the overall box or holes with grounded contacts to create a card presence circuit.

The circuit pack filler according to the embodiments has the following benefits over the typical industry solution:
a. Removes the need and cost of a PCB that guides a circuit pack to a connector.
b. Removes the need for EMI gaskets and fastening in the corners
c. Provides gasket grooves to allow inexpensive small profile EMI gaskets to seal mating parts.
d. Allows the frame to create an EMI sealed box that can control air flow through a card slot.

Typically, the networking equipment described herein is packaged and shipped in multiple boxes and containers to protect each of the components during the shipping process. For example, if one component (e.g., a pluggable module) were to be inserted into a socket of another component (e.g., a circuit pack) such that the connectors of the two components were engaged, the pins and contacts of these connectors could easily be damaged by the vibrations that would normally be experienced during shipment. To avoid excessive wear to these connectors, the normal procedure for shipping the network equipment includes keeping the components separated from each other.

### Filler Card Presence Detection

In a chassis based system in which circuit cards are inserted, there can be a backplane where all the modules or cards are connected to. Disadvantageously, a backplane is purely electrical and there are benefits to replace the backplane with cabled interconnect between modules. The control system of a chassis based system needs to know if a card is present in every slot in order to control air flow and raise alarms due to empty slots which allow air to by-pass other slots. Traditionally a low cost filler is used to fill a slot where a more expensive circuit card is needed. These fillers have had connectors on them in the past which connect to a mating connector on a backplane. The shorting of a circuit on this filler card connector allows detection of a card in this slot, which can indicate to the customer that a slot is empty which can affect the airflow design of the chassis based system.

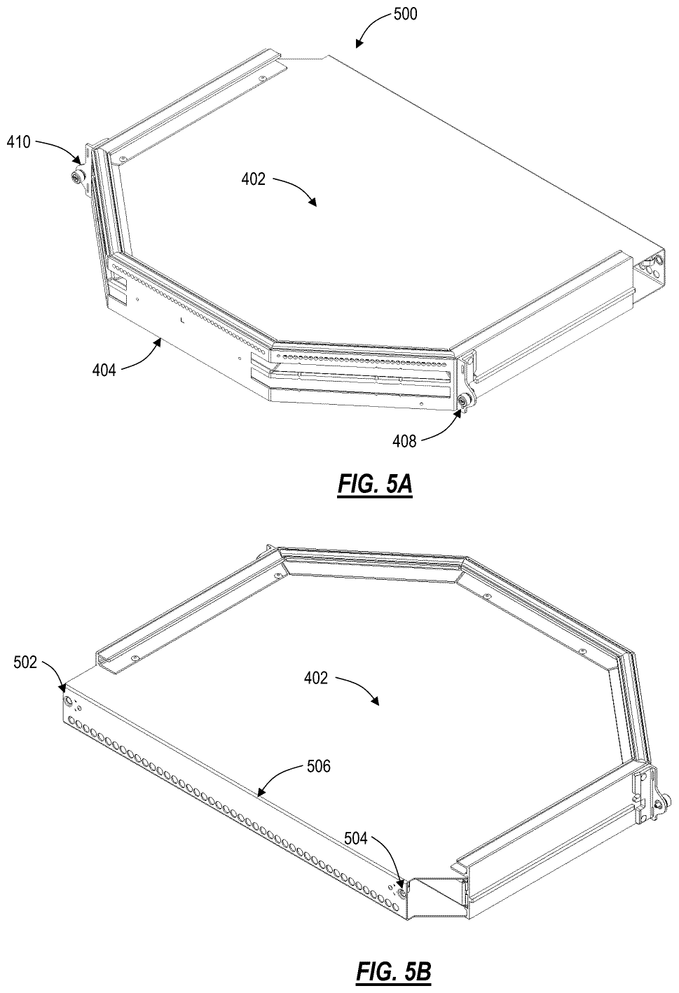

As depicted in FIGS. 5A-5B the assembled circuit pack filler is shown with novel presence detection. FIG. 5A depicts a top plate 402 which is inserted into the extrusion channel 404, where the extrusion channel 404 can include latches or mounting features (408, 410) to the front corners of the circuit pack without compromising the faraday cage. These mounting features are used to mount this circuit pack in the overall box. The circuit pack is shaped to allow air to flow over the top and bottom in controlled amounts and holes are machined in the faceplate as well as the top plate to control the amount of area the air has to enter the card slot. The top plate 402 includes a fold on the back side of the filler card circuit pack which allows guiding the filler card into a backplane. The circuit pack 500 prevents larger amounts of air from flowing in the middle of a slot and can direct air to the top and bottom of the slot toward adjacent cards that may need the air flow for cooling.

FIG. 5B illustrates the back side of the circuit pack including a baseplate without the use of an expensive PCB. The back side of the top plate is bent 506 and includes guide pin holes (502, 504) where the guide pin holes function to assist the guide pins (located on the backplane) into the back of the bent top plate on the backside of the circuit pack. There exists electrical contacts (602, 604) located on the inside of the back side of the top plate 402 close to the guide pin holes where the guide pins make contact with the electrical contacts (602, 604). The electrical connection between the electrical contacts (602, 604) and the guide pins (606, 608) on the backplane create a short circuit between the guide pins to signal the filler card is installed in the slot.

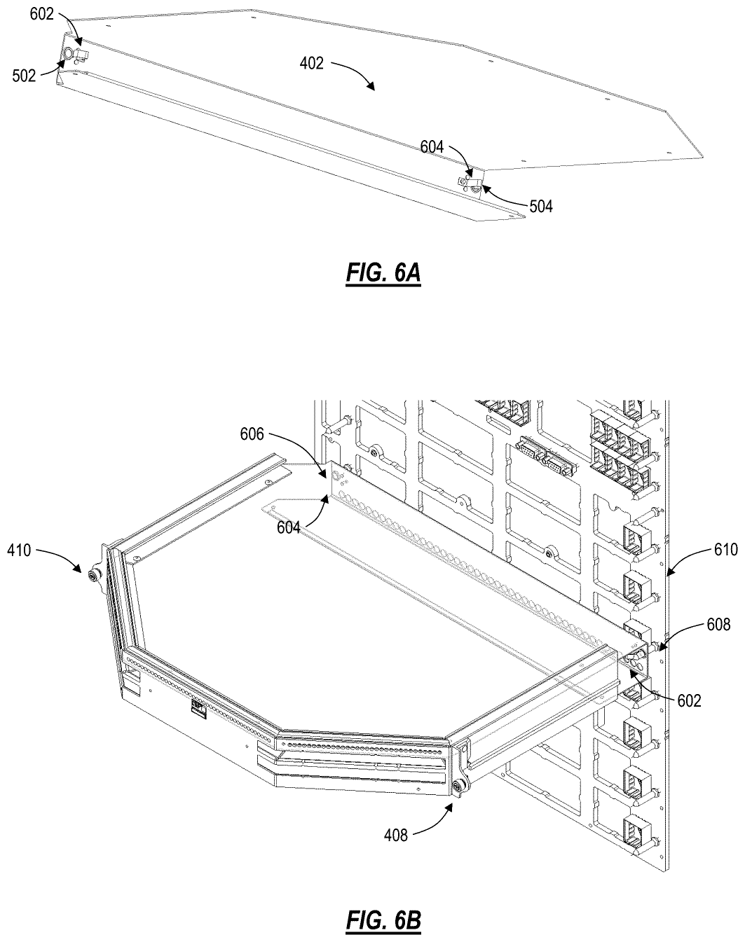

FIGS. 6A-6B further illustrate the circuit filler pack interface with the backplane. The top plate 402 is shown oriented in FIG. 6A such that the backside of the top plate includes the electrical contacts (602, 604) which make contact with the guide pins (606, 608) to create a ground path through the left and right guide pins on the backplane (610). The electrical contacts (602, 604) are shown on the backside of the top plate (402) which are positioned in relation to the guide pin holes (502, 504) such that when the circuit filler pack is installed on the backplane 610 the guide pins will align with the guide pin holes (502, 504). FIG. 6B illustrates the circuit filler pack being installed on the backplane 610 with the proper alignment such that the electrical contact 602 makes contact with the guide pin 608, wherein the guide pin 608 fits into the guide pin hole 502. Similarly, the electrical contact 604 makes contact with the guide pin 606, wherein the guide pin 606 fits into the guide pin hole 504. The ground path that is formed can be used to detect if a working card is occupying each slot. The electrical contacts (602, 604) are contact springs which use the force of the springs to contact the guide pins (606, 608) and are electrically connected to one another due to the top plate 402 which the electrical contacts (602, 604) are mounted upon, both of which are made of conductive materials. The circuit filler pack includes latches or mounting features (408, 410) to the front corners of the circuit pack without compromising the faraday cage. These mounting features are used to mount this circuit pack in the overall box

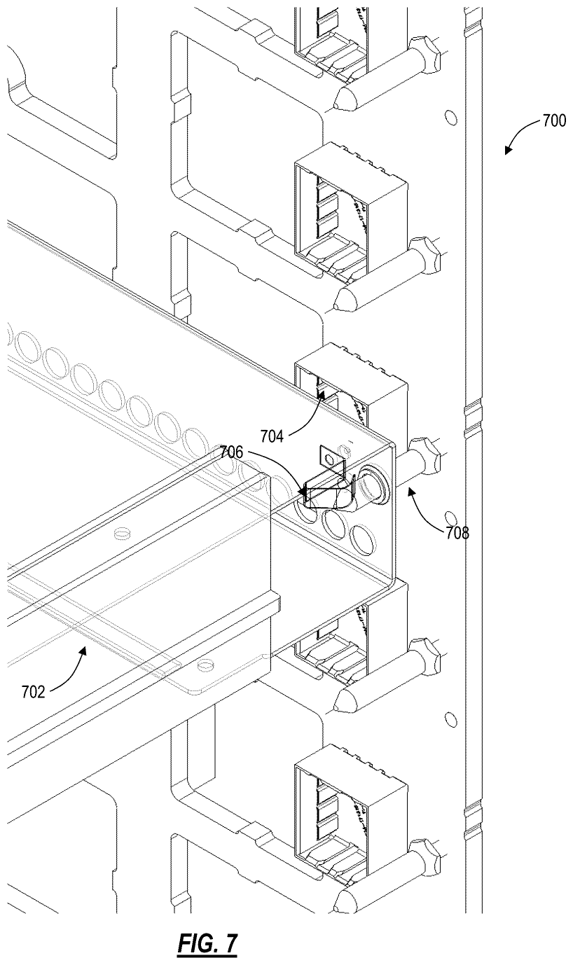

FIG. 7 is a detailed view of one side of the circuit filler pack inserted into the backplane with presence detection interfaces (700). When the circuit filler pack 702 is inserted into the shelf the electrical contact 706 makes firm contact with the guide pin 708 mounted on the backplane. This electrical connection closes a circuit that exists in the control system and the signal is sent across the backplane. This signal reaches the control modules where the shorting of the electrical circuit between the backplane and the circuit filler pack detects that a working card exists in place so there is no need to issue a slot empty alarm. The alarm would only be initiated if the short does not exist between the backplane and the circuit filler pack. The use of the circuit filler pack and inexpensive electrical contacts which have spring compression to make the electrical connection with the guide pins greatly reduces the cost of the filler cards, especially where very large circuit packs would require a very large PCB which are quite expensive to manufacturer. The typical PCB cost is approximately proportional to the PCB area and thickness, therefore the larger the PCB the larger the cost of manufacturing. The backplane includes a ground trace and guide pins (708) which creates a short circuit between the backplane and the working card and sends a signal to indicate the card is installed in the slot. The positioning of the guide pin hole 704, the guide pin 708, and the electrical contact 706 are all critical to ensure the circuit filler pack when installed on the backplane will complete the short circuit between the backplane and the working card.

The traditional way of detecting card presence includes a circuit board and connector systems which often include a small circuit on the PCB allowing the card presence signal to pass a control signal to the card in the slot. Another way of detecting card presence traditionally includes a hall effect sensor on the backplane and a magnet on the rear of the filler pack, wherein the hall effect sensor sends a signal to the control module once the magnet is detected. The hall effect sensor cannot be placed on a large passive backplane full of copper traces. This would require a different manufacturing process than available for larger backplanes. The systems and methods in the embodiments eliminate the use of a magnet and hall effect sensor providing a passive solution, the benefits of which are the following:
a. The other traditional methods require components that can fail over time
b. If components fail it would require the working card to be taken out of service to fix.

### Filler Card With Typical Pluggable Interface Feature

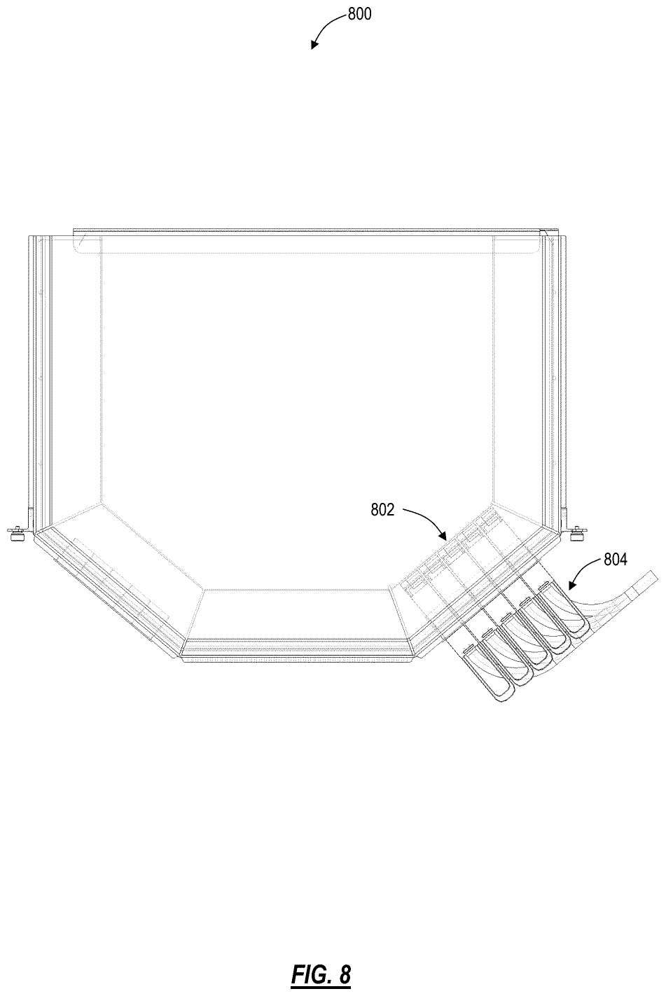

FIG. 8 is an overhead view illustrating the top of the filler card with parking slots for fabric cables. External cabling or fiber optic fabric links such as Quad Small Form-factor Pluggable Dual Density (QSFP-DD) used for data path interconnections between client/line cards and the fabric cards are used in the filler card shown 800. Traditionally, the fabric links would have existed on backplanes using traces on PCB material. These fabric cables 804 typically are pre-assembled either partially or completely which makes any additions at some future time simpler and allows for a more tidy and uniform installation of the fabric links. On the filler card the slots in the front of the module would create a parking feature 802 in order to accommodate this external cabling and would allow those cables to be parked in the provided slots which would hold the fabric cable in place until a working card which is able to manage the data traffic is used (e.g., fabric/client/line card). This filler card is used to ensure a continuous EMI cage is maintained and block any possible airflow bypass that the empty area creates before the fabric/client/line card is installed. The slots allow the initial installation and pre planning of the systems fabric link to be utilized and allow for a fast and clean installation of future fabric/client/line cards with minimal fabric link disruptions. The filler card would need to be manufactured to include slots for the anticipated number and type of fabric cables anticipated. The parking feature 802 on the faceplate of the filler card can include the following:
a. Add EMI shielded fake pluggable sockets to the filler card where the fabric link ends will connect in order to hold the fabric link in place until a fabric/client/line card is used.
b. Add fingered blades on the filler card faceplate surface to hold the fabric link ends
c. Create a tray in the filler card faceplate where the fabric link ends will be positioned.

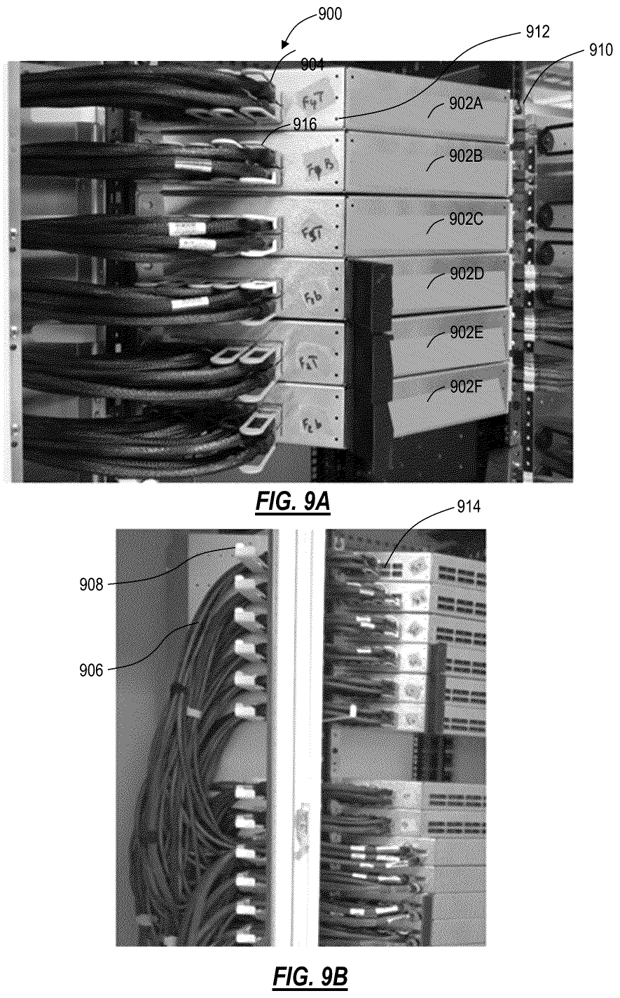

FIG. 9A-9B are perspective views of the filler card with parking slots and fabric cables installed. The plurality of filler cards (902A-902F) are shown installed in the networking rack wherein the pre-cabled fabric links are shown connected in the filler slots 904. The fabric cables 906 are further shown routed in another networking rack (FIG. 9B) wherein the cables could be routed external to the networking rack and/or routed to other working cards. The networking rack can include cabling supports 908 to assist in organizing the fabric cables before they terminate into the filler slots 904. Empty filler slots 914 exist in some of the filler cards. Arranging the fiber cabling as shown and holding the fabric cabling in the final permanent position allows for better pre-planning and installation until such a time where the final working card (fabric/client/line) is installed. The filler cards (902A-902F) are used to ensure a continuous EMI cage is maintained between the plurality of filler cards and also act to block any possible airflow bypass that the empty area creates before the fabric/client/line card is installed. The filler slots 904 allow the initial installation and pre planning of the systems fabric links to be utilized and allow for a fast and clean installation of future fabric/client/line cards with minimal fabric link disruptions. The mounting features 910 that are part of the filler cards (902A-902F) are used to mount this filler card to the shelf and to protect against seismic and office vibrations. The filler card (902A-902F) and faceplate is shaped to allow air to flow over the top and bottom in a controlled fashion. Holes 912 are machined in the faceplate to control the amount of area the air has to enter the card slot. The circuit pack filler prevents larger amounts of air flowing from flowing into the middle of a slot before the fabric/client/line card is installed.

The fabric cables shown include a pluggable module such as a Quad Small Form Factor Pluggable (QSFP) or a variant thereof and include electrical and optical elements which may be partially exposed, for example a front side of the head of the pluggable module includes an optical interface. The pluggable module may also include a handle 916 that can be used for inserting or removing the pluggable module into the corresponding slot associated with the filler card. These fabric cables would need to be individually removed prior to installing a working card.

### Cable Parking System for a Network Element

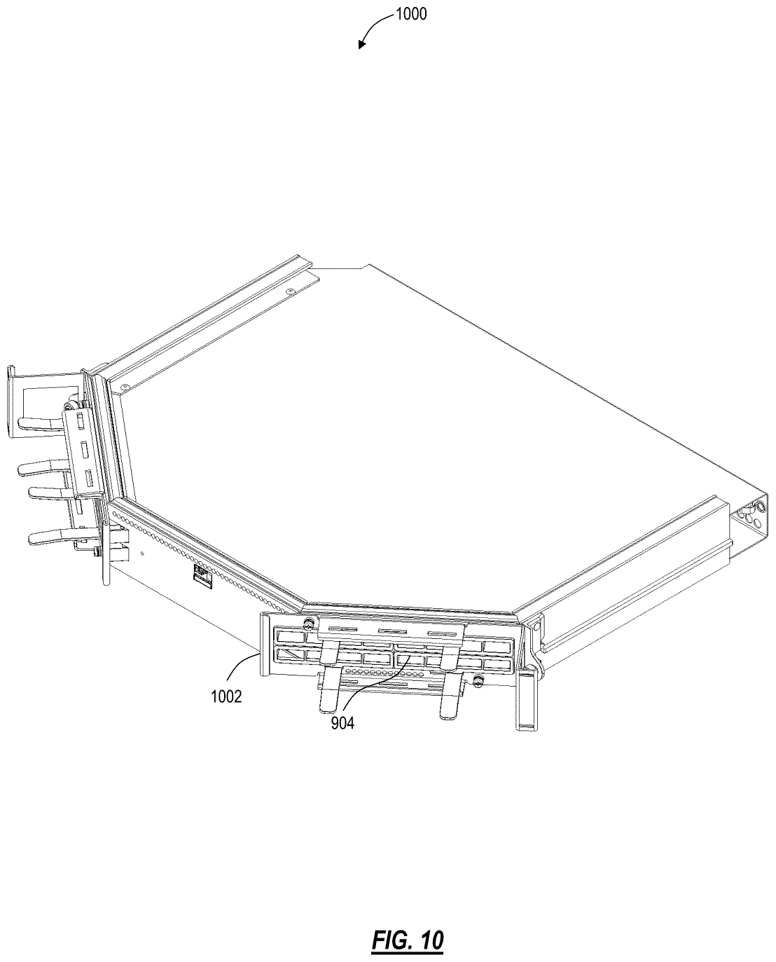

FIG. 10 illustrates an isometric view of a fully expandable filler card module for pre-cabling data links, according to various embodiments. This filler card would be part of a networking system rack wherein a backplane does not exist for fabric data path between client and line cards like traditional methods. The networking system described relies on the use of externally connected cables or fibers such as but not limited to Direct Attach Cables (DACs), Active Electrical Cables (AECs), Active Optical Cables (AOCs), etc.) to make the fabric connections. The system architecture is designed to be fully expandable for future capability, therefore the customer does not need to fill the circuit pack shelf with client cards upon installation. Customers can purchase additional working cards as the demand requires new working cards. The shelf must be deployed with all filler slots 904 populated to maintain airflow balancing in addition to providing EMI integrity. The filler card 1000 depicts a module intended for installation in a networking rack wherein pre-cabling most if not all of the fabric links would be very beneficial to the customer. The pre-cabling would make any line card additions at a future time much simpler and require much less installation time at the start of system deployment as the pre-cabling would be terminated into the filler slots 904. Since all fabric modules must be deployed during networking start up, the fabric module end of the DAC can be connected to the fabric modules. The client/line module end of the DAC needs to be in place to connect to until an actual client/line card is installed.

As shown in FIG. 10 a feature can be added to the filler card 1000 which would allow the parking of pluggable modules such as the QSFP-DD until a time where the actual fabric or client card is required. The parking feature 1002 is designed to:
a. Allow the mating of pluggable modules such as QSFP-DD (From DACs, AECs, AOCs, etc.), however can be designed to accommodate many other types.
b. Protect the QSFP-DD modules from damage during filler card replacement by using removable parking features.
c. Allow the upgrade of the filler card to a working card such as a fabric park or line park card.
d. Allow shipping pre-assembled cables in place which include pre-cabling to the filler card prior to shipment into the field which provides a turnkey solution for customers that prefer not to have to terminate cabling in the field.
e. Include features for providing strain relief to cables exiting park modules during shipping and transport.

It should be noted as described according to various embodiments that the parking feature 1002 has the ability to be expanded to include any variety of electrical or optical modules that the networking system could potentially plan on using in the future. The parking feature can be applied to various filler card configurations with various slot configurations.

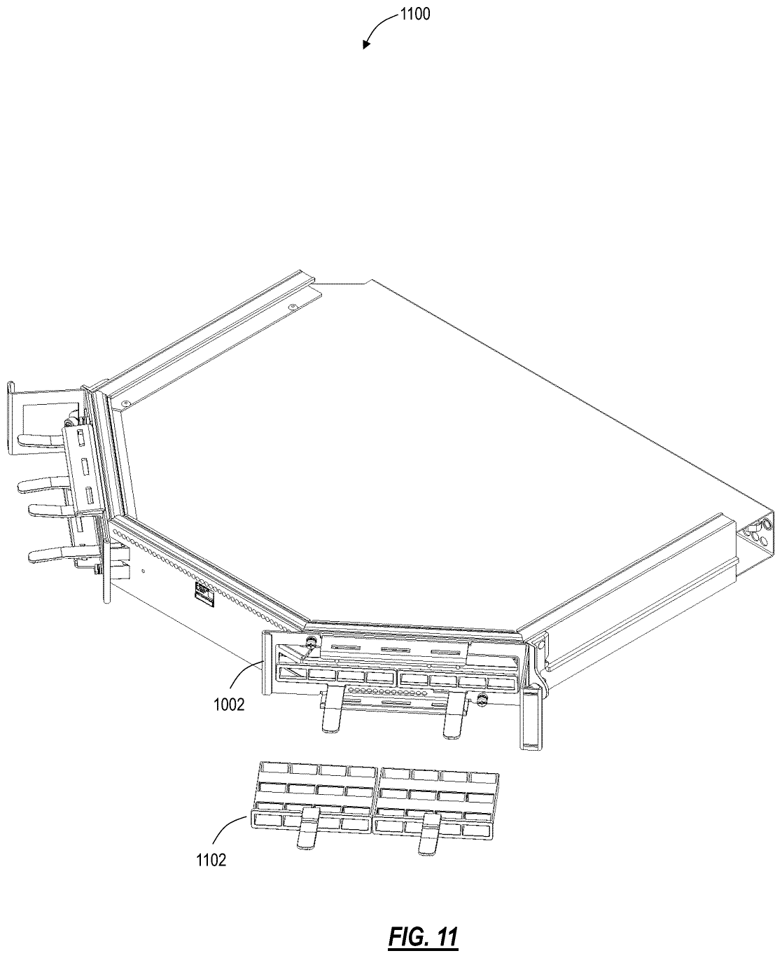

FIG. 11 illustrates an isometric view of a fully expandable filler card for pre-cabling data links including a QSFP-DD holder, according to various embodiments. The filler card 1100 is shown with parking feature 1002 as described in various embodiments. The parking feature can also include pluggable module holders 1102 which can be used in a plurality of parking modules. Each pluggable module holder is configured to insert in a corresponding park module and each configured to hold a pluggable module with a cable connected thereto. The pluggable module holders 1102 are removable from the park module with the plurality of cables attached thereto, for replacing the filler card with a working card. The working card includes one or more of a client card, a line card, a fabric card, and a combination thereof. The pluggable module holders 1102 also provide support at the end of each of the plurality of cables which can assist in proper routing of cabling outside the networking rack/cabinet and thereby reducing the number of cabling supports required inside the networking rack/cabinet. By adding the pluggable module holders 1102 to the parking feature the entirety of the various cabling can be removed from the filler card at once instead of the typical arrangement where each pluggable module needs to be removed separately. The pluggable module holders maintain the fabric cabling in their corresponding slots throughout the removal of the filler card and the installation of the working card.

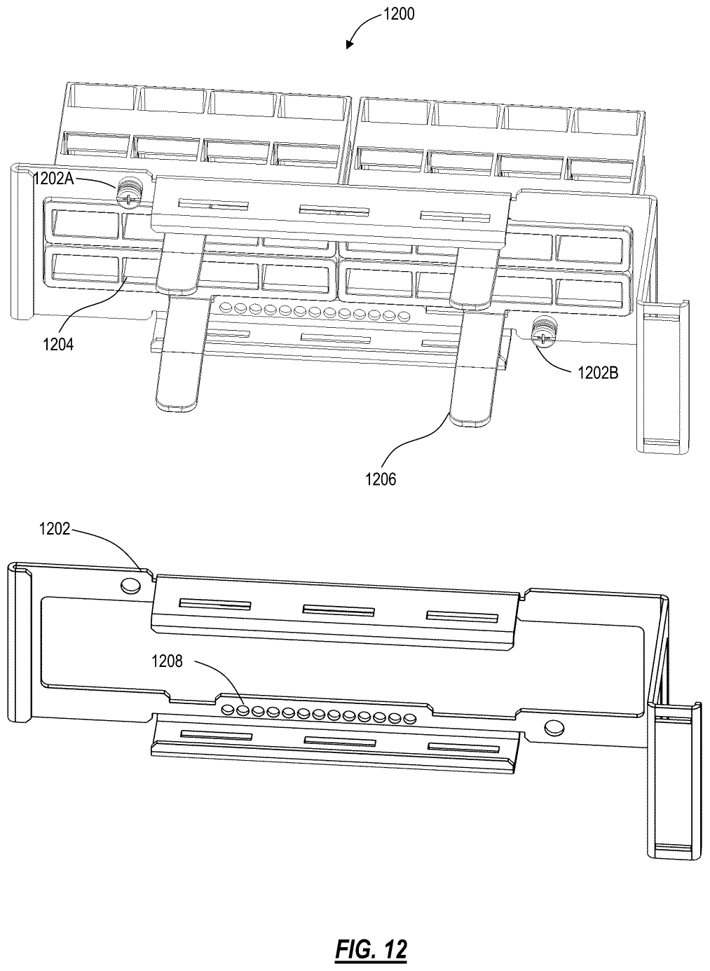

FIG. 12 illustrates an isometric view of the parking module for a filler card, according to various embodiments. The parking module 1202 is attached to the filler card 1100 by using screws, clamps, springs, or other mounting means (1202A-1202B). The parking module 1202 can accommodate different slot configurations 1204 that can be customized based on the type of working card necessary wherein the working card can include a line card, fabric card, client card, etc. The parking module 1202 includes holes 1208 which can assist in controlling airflow into the filler card. It is best to direct air to the top and bottom of the slot toward adjacent cards that may need the air flow for cooling when a filler card is present.

The filler cards can be upgraded at customer sites by ordering module upgrade kits where these upgrade kits would easily transform the filler card 1100 into a line card park module or a fabric card park module. The fully expandable filler card and parking module also include pluggable module holders 1206 which can be removed from the parking module using the handles on the front of the pluggable module holders. Each pluggable module holder is configured to insert in a corresponding park module and each configured to hold pluggable modules with a cable connected thereto. The pluggable module holders 1206 are removable from the park module with the plurality of cables attached thereto, for replacing the filler card with a working card that includes one or more of a client card, a line card, a fabric card, and a combination thereof. The filler card kits can include the following as needed:
a. Park module (simple filler, with a placeholder for eventual upgrade to QSFP-DD part features)
b. Park module kit, 20× QSFP-DD (added to client/line slots)
c. Park module kit, 32× QSFP-DD (added to fabric slots)
d. Low cost park module kit, reduced feature set, simple sheet metal faceplate

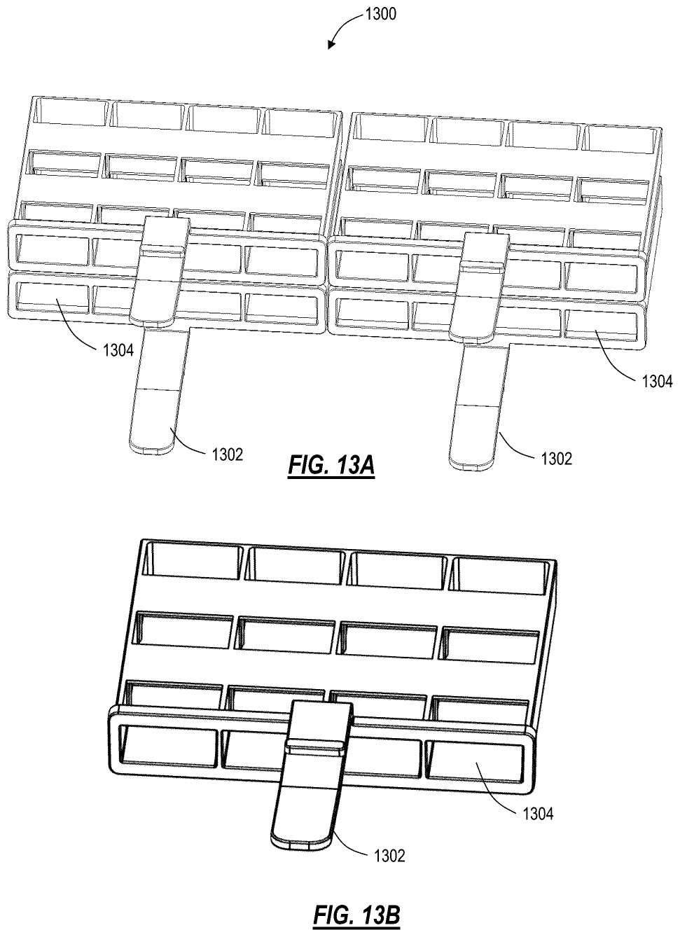

FIGS. 13A-13B illustrate detailed views of the pluggable module holders. The pluggable module holders 1300 are removable from the park module with the plurality of cables attached thereto, for replacing the filler card with a working card that includes one or more of a client card, a line card, a fabric card, and a combination thereof. Each pluggable module holder is configured to insert in a corresponding park module and each pluggable module holder slots 1304 configured to hold a pluggable module with a cable connected thereto. The pluggable module holders can be configured as a two high (2×) as shown in FIG. 13A or a one high (1×) as shown in FIG. 13B depending on the need from the client for future capabilities. The holders can be used with a cage/connector system similar or equal to QSFP-DD where the fabric cables are connected to the cage/connector and pre-wired to the filler card for anticipation of the filler card being replaced with a working card. When the client replaces the filler card with a working card, the pluggable module holders 1300 can be removed easily and provide protection to the fabric cables during swap out of the park module and circuit filler pack. The pluggable module holder includes a handle 1302 located on the front of the module which allows the customer to remove the holder with fabric cables continuing to be connected to the pluggable module holder slots 1304. The cable pluggable module which fits into the pluggable module holder slots 1304 includes electrical and optical elements residing with a housing that includes a head and an elongated body. The new working card can be installed in the networking rack and the pre-cabled fabric cables can be connected to the working card. The pluggable module holders can be part of a park module kit where the customer can order either a line card park module including 20× QSFP-DD for client/line slots or a fabric park module including 32× QSFP-DD fabric slots.

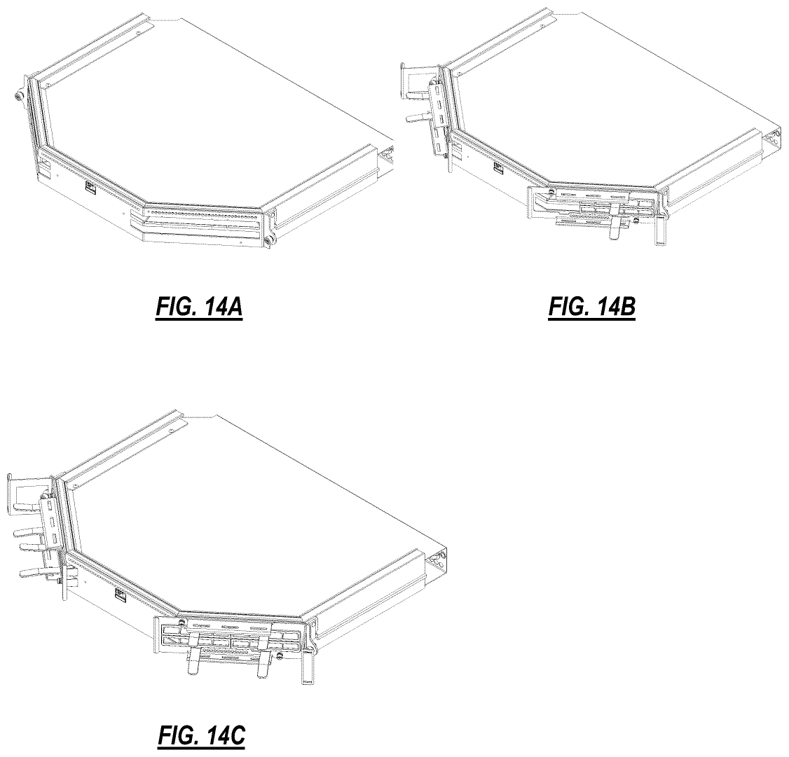

FIGS. 14A-14C are detailed illustrations for various park and filler cards, according to various embodiments. The park and filler card modules can be ordered by the customer in pre-assembled kits or can be ordered as upgrade kits to be used to upgrade customer sites. The filler card can be easily upgraded to a fabric park module or a line card park module by ordering a park module upgrade kit. The filler cards and park modules include the following features:
a. Slot presence detection/alarm: The shelf can identify when a filler is present by grounding of the guide pins 708. When the module is inserted into the shelf the electrical contact 706 on the filler card makes electrical contact with the guide pin 708 mounted on the backplane of the chassis. This electrical circuit acts as an open contact being closed when the guide pins 708 on the backplane make contact with the electrical contact 706 on the filler card. This electrical circuit is wired to the control system so that the control system can determine if a card is present in every slot in order to control air flow and raise alarms due to empty slots which allow air to bypass other slots. This method of slot presence detection is much simpler and cost effective when compared to the typical PCB type method of detection.
b. EMI/Faraday cage: The circuit pack filler is designed with EMI gaskets (202, 204) that contact the shelf and adjacent cards. The internal gasket design allow for larger cutouts to be present in the faceplate without the need for traditional faceplate EMI solutions such as EMI rated plug dust covers.
c. System thermal integrity: The circuit pack filler is shaped to allow air to flow over the top and bottom in controlled amounts, holes are machined in the faceplate to control the amount of area the air has available to enter the filler card slot. The circuit pack prevents larger amounts of air from flowing in the middle of a slot. It is best to direct air to the top and bottom of the slot toward adjacent cards that may need the air flow for cooling.

FIG. 14A depicts a simple filler card module which includes a simple filler with placeholder for eventual upgrade to QSFP-DD park features. The filler card module can be upgraded by the customer to a line park module or a fabric park module by transforming the filler card module with filler/park module kits. The filler card module as shown does not include park modules and pluggable module holders but would include slot presence alarm features, EMI cage design, and system thermal integrity features due to thermal balancing. The open slots in the front are intended to be used with a park module configured to attach to the faceplate and receive a plurality of cables for connectivity between the plurality of slots.

FIG. 14B depicts a low cost park module which is a low cost variation to the park module design. The low cost park module includes a simple sheet metal faceplate design that can be utilized with park modules and QSFP-DD pluggable module holders. This solution would be used for a ship in place solution and the intent of this variation is the following:
a. Provide a place to park QSFP-DDs of a pre-cabled system, to be shipped to a customer.
b. Protect QSFP-DD modules during swap out of the park module and circuit pack filler.
c. The reduced feature set and simple sheet metal faceplate can be discarded after the swap out of the working card as the module is much less costly than other filler cards.

FIG. 14C illustrates a client park module kit which includes a filler card including a park module and pluggable module holders for 20× QSFP-DD pre-assembled kits. This module kit can also be ordered as upgrade kits to be used to upgrade customer sites that have a filler card installed. Each pluggable module holder is configured to insert in a corresponding park module and each configured to hold a plurality of pluggable modules with a plurality of cables connected thereto. The pluggable module holders are removable from the client park module with the plurality of cables attached thereto, for replacing the filler card with a working card. The fabric park module kit installed on the filler card would provide slot presence detection, EMI protection, air flow balancing, support for fabric cables, and provides a faster more organized alternative for swapping out a filler card for a working card.

There is also a fabric park module kit which includes a filler card module including a park module and pluggable module holders for 32× QSFP-DD pre-assembled kits. This fabric module kit can also be ordered as upgrade kits to be used to upgrade customer sites. Each pluggable module holder is configured to insert in a corresponding park module and each pluggable module holder is configured to hold a plurality of pluggable modules with a plurality of cables connected thereto. The pluggable module holders are removable from the fabric park module with the plurality of cables attached thereto, for replacing the filler card with a working card. The fabric park module kit installed on the filler card would provide slot presence detection, EMI protection, air flow balancing, support for fabric cables, and provides a faster more organized alternative for swapping out a filler card for a working card.

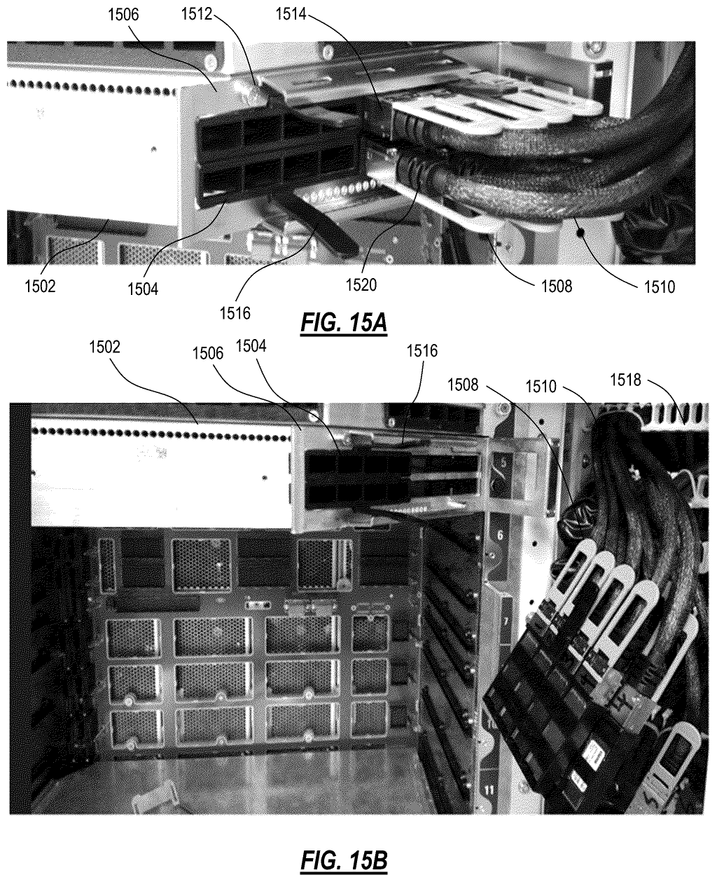

FIGS. 15A-15B are front views of a networking rack including filler cards and park modules with pre-assembled cabling. As shown in FIG. 15A the filler card 1502 is installed into the networking rack configured to be inserted in a slot of a plurality of slots, wherein the filler card 1502 includes a shelf containing the plurality of slots. The filler card 1502 includes a park module 1506 with fixed mounting screws 1512 that secures the park module 1506 to the filler card 1502. The pluggable module holders 1504 are inserted into the plurality of slots associated with the filler card 1502 and can include a pre-assembled fabric cable system 1510. In a pre-assembled fabric cable system 1510 it may be desirable to ship the pre-cabled system to simplify the set up process on site, also the cabled system can be tested in the factory and shipped where the customer may be able to set up the equipment on site for a faster field installation. The pluggable module which fits into the pluggable module holders 1504 includes electrical and optical elements residing with a housing that includes a head 1514 and an elongated body 1520. A pluggable module can be a Quad Small Form Factor Pluggable (QSFP) or a variant thereof and includes electrical and optical elements which may be partially exposed, for example a front side of the head 1514 of the pluggable module includes an optical interface. The pluggable module may also include a handle 1508 that can be used for inserting the pluggable module into the corresponding slot associated with the pluggable module holder 1504. The pluggable module holders 1504 hold the pre-assembled fabric cable system 1510 in place and when the filler card module gets swapped out with a working card, the pluggable module holders can be removed from the filler card parking module and keep the cable system together where individual cables are not separated from one another.

The park module does not impact the airflow or EMI design as the park module can include air holes to assist in thermal balancing. The park module provides support for cabling in order to ship in place without eroding QSFP-DD contacts due to vibration, the park module also reduces weight relative to a pack in place method of packing and shipping. Another benefit of the removable park modules are that they provide a physical topology template via a pre-assembled fabric cable system 1510 that facilitates installation but the customer. The park module 1506 keeps the fabric cables in their exactly location throughout the swap out of the filler card with the working card which prevents re termination errors that can occur on site in addition to protecting cable ends during the swap out. The typical method for parking cables includes tie wrapping cables to a support feature nearby, however this does not allow for proper module protection and space is typically limited at the rack faceplate so tie wrapping is not always feasible.

As further depicted in FIG. 15B the filler card 1502 is installed in the networking rack where the filler card 1502 includes a park module 1506 with fixed mounting screws 1512 that secures the park module 1506 to the filler card 1502. The pluggable module holders 1504 are shown where one set of pluggable module holders shown on the left side of the filler card 1502 do not have cabling attached and the other pluggable module holders on the right side of the filler card 1502 includes a pre-assembled fabric cable system 1510. This illustration shows the pluggable module holder 1504 with the pre-assembled fabric cable system 1510 removed from the filler card 1502. The handles 1516 on the pluggable module holder aid in the quick removal of the pluggable module holder 1504 from the filler card module and also keep the cabling organized by maintaining the position of each cable in the associated filler card slot. Removing the pluggable module holder 1504 from the park module 1506 can allow swapping the filler card 1502 for a working card such as a client, line, or fabric card.

The networking rack can include cabling supports 1518 to assist in organizing the fabric cables and providing additional support before they terminate into the pluggable module holder 1504. Arranging the fabric cabling as shown and holding the fabric cabling in the final permanent position allows for better pre-planning and installation when the final working card (fabric/client/line) is installed.

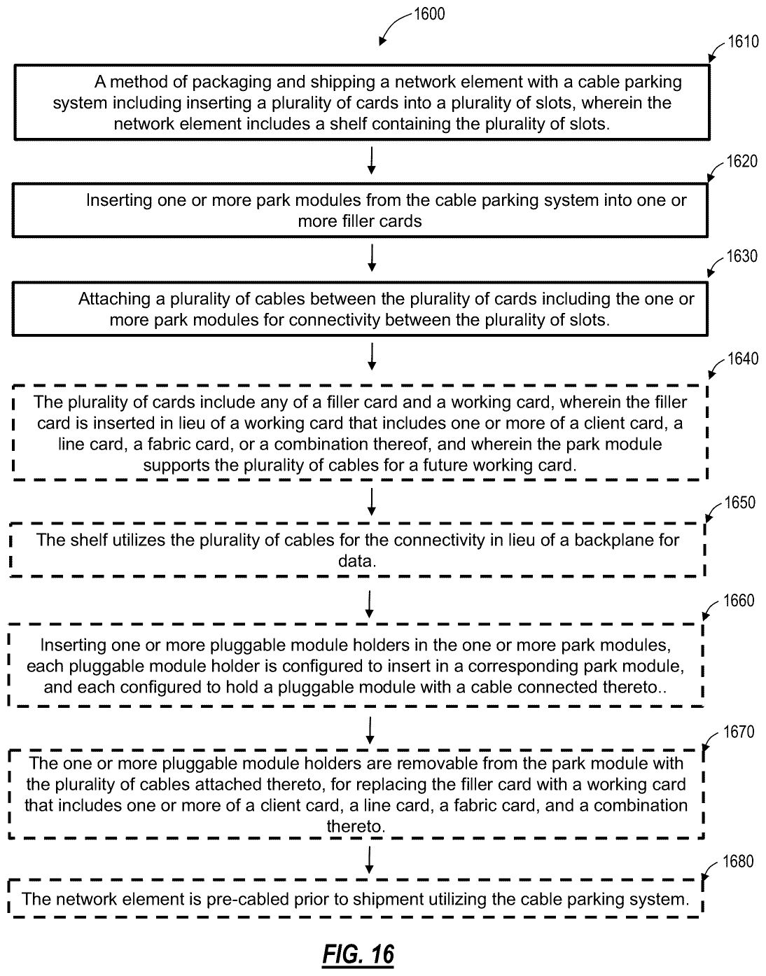

FIG. 16 is a flowchart illustrating an embodiment for a method of packaging and shipping a network element with a cable parking system. The method 1600 can be performed in any sequence or operation as shown in various embodiments. The shipping and packaging of the network element with a cable parking system comprising inserting a plurality of cards into a plurality of slots, where the network element includes a shelf containing a plurality of slots (1610). The parking system including park modules which can be inserted into one or more filler cards (1620). The pre-assembled cables attached between the cards including the one or more park modules for connectivity between the plurality of slots (1630). The plurality of cards include filler cards and working cards where the filler card is inserted in lieu of a working card. A working card can include one or more client card, line card, fabric card, or a combination thereof. The park module supports the plurality of pre-assembled cables for a future working card (1640). The network element shelf utilizes the plurality of cables for the connectivity in lieu of a backplane for data (1650).

The method of packaging and shipping a network element including inserting one or more pluggable module holders in the one or more park modules where each pluggable module holder is configured to insert in a corresponding park module. Each park module is configured to hold a pluggable module such as a QSFP-DD with a cable connected to the pluggable module (1660). The pluggable module holders are removable from the park module where the cables are maintained in their same location throughout the swap out of the filler card with a working card. The ability to remove the park module with the cables attached allows replacing the filler card with a working card (client card, fabric, card, line card, or combination) much faster, easier, and more beneficial to the customer (1670). The pluggable modules can include a QSFP or similar variant and the plurality of cables can also include any of Active Electrical Cable (AEC), Active Optical Cable (AOC), and Direct Attach Cable (DAC). The network element is pre-cabled prior to shipment utilizing the cable parking system (1680). The park module provides support for cabling in order to ship in place without eroding QSFP-DD contacts due to vibration, the park module also reduces weight relative to a pack in place method of packing and shipping.

### CONCLUSION

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following claims. The foregoing sections may include headers for various embodiments and those skilled in the art will appreciate these various embodiments may be used in combination with one another as well as individually. Further, it is noted that the various elements, operations, steps, methods, processes, algorithms, functions, techniques, etc. described herein can be used in any and all combinations with one another.

What is claimed is:

1. A cable parking system for a network element, comprising:
a filler card configured to be inserted in a slot of a plurality of slots, wherein the network element includes a shelf containing the plurality of slots; and
a park module configured to attach to a faceplate of the filler card and configured to receive and hold a plurality of cables for connectivity between the plurality of slots.

2. The cable parking system of claim 1, wherein the filler card is inserted in lieu of a working card that includes one or more of a client card, a line card, a fabric card, and a combination thereof, and wherein the park module supports the plurality of cables for a future working card.

3. The cable parking system of claim 1, wherein the shelf utilizes the plurality of cables for the connectivity in lieu of a backplane for data.

4. The cable parking system of claim 1, further comprising
one or more pluggable module holders, each configured to insert in the park module and each configured to hold one or more pluggable modules with a cable connected thereto.

5. The cable parking system of claim 4, wherein a pluggable module of the one or more pluggable modules is a Quad Small Form Factor Pluggable (QSFP), Small Form Factor Pluggable (SFP), Octal SFP (OSFP), or a variant thereof.

6. The cable parking system of claim 4, wherein the one or more pluggable module holders are removable from the park module with the plurality of cables attached thereto, for replacing the filler card with a working card that includes one or more of a client card, a line card, a fabric card, and a combination thereof.

7. The cable parking system of claim 4, wherein the plurality of cables include any of an Active Electrical Cable (AEC), Active Optical Cable (AOC), and Direct Attach Cable (DAC).

8. The cable parking system of claim 4, wherein the one or more pluggable module holders protectively support an end of each of the plurality of cables.

9. The cable parking system of claim 1, wherein the filler card and the park module are present with the network element operating, such that the filler card and the park module support airflow and Electromagnetic Interference (EMI) protection for the shelf.

10. The cable parking system of claim 1, wherein the network element is pre-cabled prior to shipment utilizing the cable parking system.

11. A method of packaging and shipping a network element with a cable parking system, the method comprising:
inserting a plurality of cards into a plurality of slots, wherein the network element includes a shelf containing the plurality of slots;
inserting one or more park modules from the cable parking system into one or more filler cards of the plurality of cards; and
attaching a plurality of cables between the plurality of cards, including the one or more park modules, for connectivity between the plurality of slots.

12. The method of claim 11, wherein the plurality of cards include any of a filler card and a working card, wherein the filler card is inserted in lieu of a working card that includes one or more of a client card, a line card, a fabric card, and a combination thereof, and wherein the park module supports the plurality of cables for a future working card.

13. The method of claim 11, wherein the shelf utilizes the plurality of cables for the connectivity in lieu of a backplane for data.

14. The method of claim 11, further comprising
inserting one or more pluggable module holders in the one or more park modules, each pluggable module holder is configured to insert in a corresponding park module and each configured to hold a pluggable module with a cable connected thereto.

15. The method of claim 14, wherein a pluggable module of the one or more pluggable modules is a Quad Small Form Factor Pluggable (QSFP), Small Form Factor Pluggable (SFP), Octal SFP (OSFP), or a variant thereof.

16. The method of claim 14, wherein the one or more pluggable module holders are removable from the park module with the plurality of cables attached thereto, for replacing the filler card with a working card that includes one or more of a client card, a line card, a fabric card, and a combination thereof.

17. The method of claim 14, wherein the plurality of cables include any of an Active Electrical Cable (AEC), Active Optical Cable (AOC), and Direct Attach Cable (DAC).

18. The method of claim 14, wherein the one or more pluggable module holders protectively support an end of each of the plurality of cables.

19. The method of claim 11, wherein the filler card and the park module are present with the network element operating, such that the filler card and the park module support airflow and Electromagnetic Interference (EMI) protection for the shelf.

20. The method of claim 11, wherein the network element is pre-cabled prior to shipment utilizing the cable parking system.
